(19) United States
(12) Patent Application Publication
(10) Pub. No.: US 2009/0170270 A1
(43) Pub. Date: Jul. 2, 2009

(54) INTEGRATION SCHEMES TO AVOID FACETED SIGE

(75) Inventors: Srinivasan Chakravarthi, Murphy, TX (US); Periannan Chidambaram, Richardson, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/212,060

(22) Filed: Sep. 17, 2008

Related U.S. Application Data
(60) Provisional application No. 61/016,974, filed on Dec. 27, 2007.

(51) Int. Cl. H01L 21/336

(52) U.S. Cl. 438/300; 257/E21.431

(57) ABSTRACT

Semiconductor devices and fabrication methods are provided in which disposable gates are formed over isolation regions. Sidewall structures, including disposable sidewall structures, are formed on sidewalls of the disposable gates. An epitaxially grown silicon germanium is formed in recesses defined by the sidewalls. The process provides a compressive strained channel in the device without faceting of the epitaxially grown silicon germanium.

### RELATED APPLICATION

This application claims priority to Ser. No. 61/016,974 filed Dec. 27, 2007, which is entitled “Integration Schemes to Avoid Faceted Sige.”

### FIELD OF INVENTION

The present invention relates generally to semiconductor devices and associated methods of manufacture.

### BACKGROUND OF THE INVENTION

A conventional MOS transistor generally includes a semiconductor substrate, such as silicon, having a source, a drain, and a channel positioned between the source and drain. A gate stack composed of a conductive material (a gate conductor), an oxide layer (a gate oxide), and sidewall spacers, is typically located above the channel. The gate oxide is typically located directly above the channel, while the gate conductor, generally comprised of polycrystalline silicon (polysilicon) material, is located above the gate oxide. The sidewall spacers protect the sidewalls of the gate conductor.

Generally, for a given electric field across the channel of a MOS transistor, the amount of current that flows through the channel is directly proportional to a mobility of carriers in the channel. Thus the higher the mobility of the carriers in the channel, the more current can flow and the faster a circuit can perform when using high mobility MOS transistors. One way to increase the mobility of the carriers in the channel of an MOS transistor is to produce a mechanical stress in the channel.

A compressive strained channel has significant hole mobility enhancement over conventional devices. A tensile strained channel, such as a thin silicon channel layer grown on relaxed silicon-germanium, achieves significant electron mobility enhancement. The most common method of introducing tensile strain in a silicon channel region is to epitaxially grow the silicon channel layer on a relaxed silicon-germanium (SiGe), layer or substrate. The ability to form a relaxed SiGe layer is important in obtaining an overlying, epitaxially grown, silicon layer under biaxial tensile strain, however the attainment of the relaxed SiGe layer can be costly and difficult to achieve.

Another prior art method of obtaining a compressive strain in the channel is to epitaxially grow a SiGe layer over the entire active area. However, processes using selective epitaxial deposition for the engineering of elevated source/drain regions often result in overgrowth of the SiGe layer, typically on the order of 300 to 400 Å.

Such overgrowth on free surfaces results in faceting of edges due to minimization of interfacial energy causing strain relaxation along corners and potential strain in the channel. Similar to free surfaces, faceting also occurs in the presence of an oxide.

Thus, SiGe along the edge of a shallow trench isolation (STI) is faceted, resulting in decreased strain in narrow devices.

It would be advantageous to have a semiconductor device and method that effectively and reliably provides strain to the device without the problems associated with faceting.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

In one embodiment, the invention is directed to a method of forming a semiconductor device comprising forming gates over a substrate, the gates including disposable gates overlying isolation regions; forming oxide offset spacers and nitride sidewall structures on sidewalls of the gates; forming recesses in areas defined by sidewall structures; filling with an epitaxially grown semiconductor material; forming a source region and a drain region by doping a first portion and a second portion of active regions adjacent a gate; and activating the dopants in the source region and the drain region by heating the active regions.

In another embodiment, the invention is directed to a method of forming a semiconductor device comprising forming gates over a substrate, the gates including disposable gates overlying isolation regions; forming nitride offset spacers and oxide sidewall structures on sidewalls of the gates; forming recesses in areas defined by sidewall structures; filling with an epitaxially grown semiconductor material; removing oxide sidewall structures; forming a source region and a drain region by doping a first portion and a second portion of active regions adjacent a gate; and activating the dopants in the source region and the drain region by heating the active regions.

In a further embodiment, the invention is directed to a method of forming a semiconductor device comprising forming gates over a substrate, the gates including disposable gates overlying isolation regions; forming nitride offset spacers and nitride sidewall structures on sidewalls of the gates; forming recesses in areas defined by sidewall structures; filling with an epitaxially grown semiconductor material; forming a source region and a drain region by doping a first portion and a second portion of active regions adjacent a gate; and activating the dopants in the source region and the drain region by heating the active regions.

In a still further embodiment, the invention is directed to a method of forming a semiconductor device comprising forming gates over a substrate, the gates including disposable gates overlying isolation regions; forming offset spacers and multilayer sidewall structures on sidewalls of the gates; forming recesses in areas defined by sidewall structures; filling with an epitaxially grown semiconductor material; removing a portion of the multilayer sidewall structure; forming a source region and a drain region by doping a first portion and a second portion of active regions adjacent a gate; activating the dopants in the source region and the drain region by heating the active regions.

The following description and annexed drawings set forth in detail certain illustrative aspects and implementations of the invention. These are indicative of but a few of the various ways in which the principles of the invention may be employed.

### BRIEF DESCRIPTION OF THE DRAWINGS

FIG. 1 is a flow chart illustrating a method of forming a semiconductor device according to one aspect of the invention; and

FIGS. 2A-2I and 2K are fragmentary cross section diagrams illustrating various steps of forming NMOS and PMOS transistors in accordance with FIG. 1.

FIG. 2J is a top plan view of a semiconductor device on the middle of a source/drain region in accordance with the invention.

FIGS. 2K-2L are fragmentary cross section diagrams illustrating various steps of forming NMOS and PMOS transistors in accordance with the invention of FIG. 1.

FIG. 3 is a flow chart illustrating a method of forming a semiconductor device according to an alternative aspect of the invention.

FIGS. 4A-4E are fragmentary cross section diagram illustrating a step of forming NMOS and PMOS transistors in accordance with the method of FIG. 3.

FIG. 5 is a flow chart illustrating a method of forming a semiconductor device according to an alternative aspect of the invention.

FIG. 6 is a flow chart illustrating a method of forming a semiconductor device according to an alternative aspect of the invention.

FIGS. 7A-7E are fragmentary cross section diagrams illustrating steps of forming NMOS and PMOS transistors in accordance with the method of FIG. 6.

FIG. 8 is a cross section along the width of a source/drain region in accordance with an embodiment of the invention.

FIG. 9 is a top plan view of a semiconductor device on the middle of a source/drain region.

FIGS. 10A-10B are cross sections along the width of the source/drain region of FIG. 9 illustrating a narrow width and a wide width device formed in accordance with conventional methods.

### DETAILED DESCRIPTION OF THE INVENTION

One or more implementations of the invention will now be described with reference to the attached drawings, wherein like reference numerals are used to refer to like elements throughout, and wherein the illustrated structures are not necessarily drawn to scale.

In the following description, reference is made to the accompanying drawings that form a part thereof, and in which are shown, by way of illustration, specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, not to be taken in a limited sense.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, and all sub ranges having a minimum value of equal to or greater than zero and a maximum value of equal to or less than 10, e.g., 1 to 5.

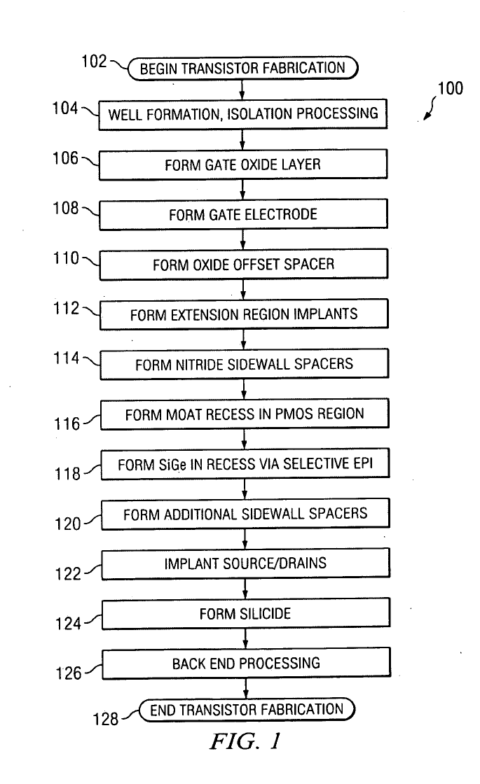

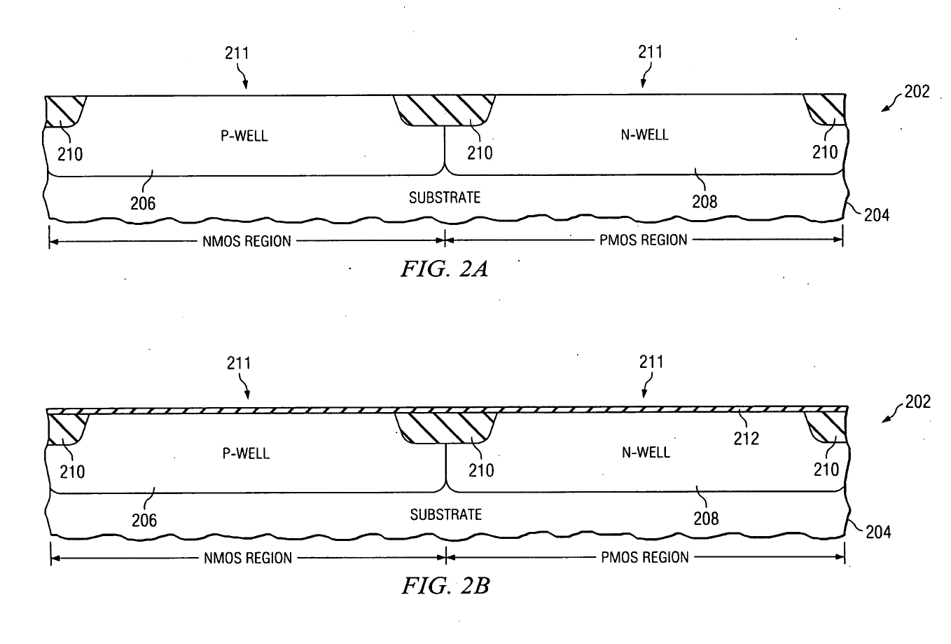

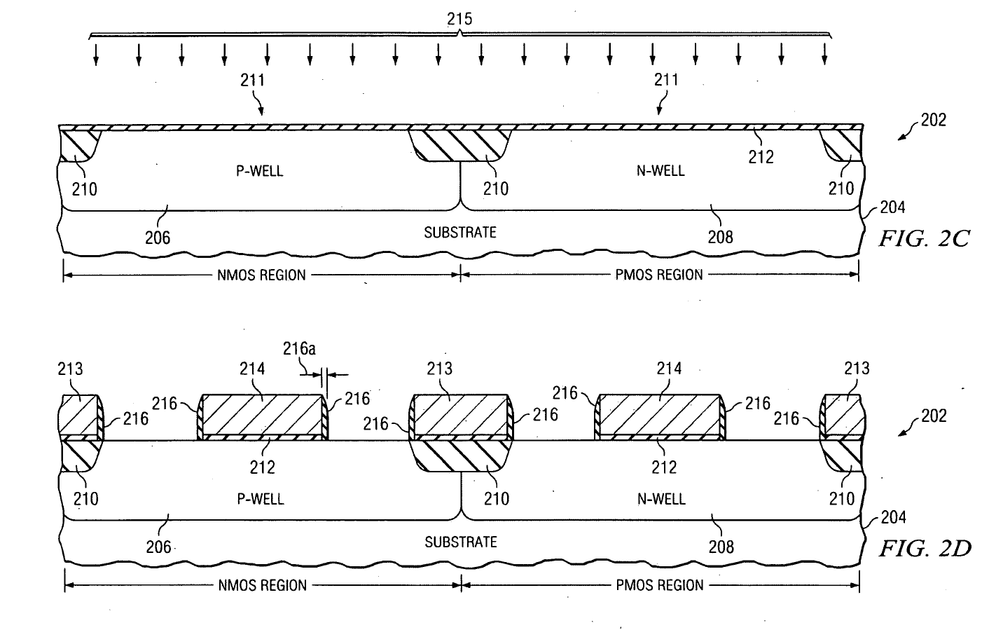

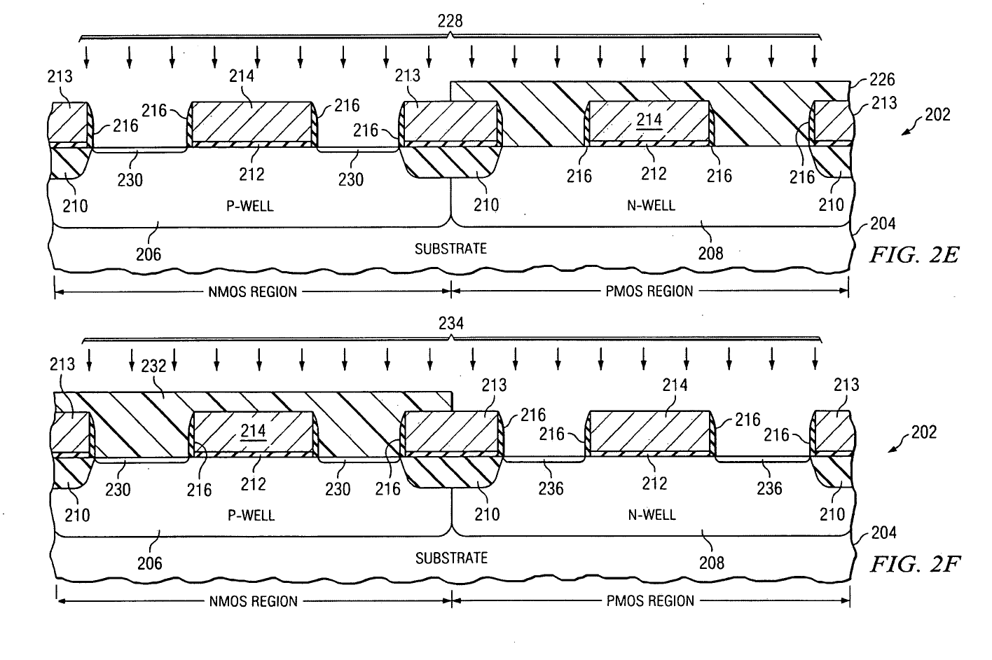

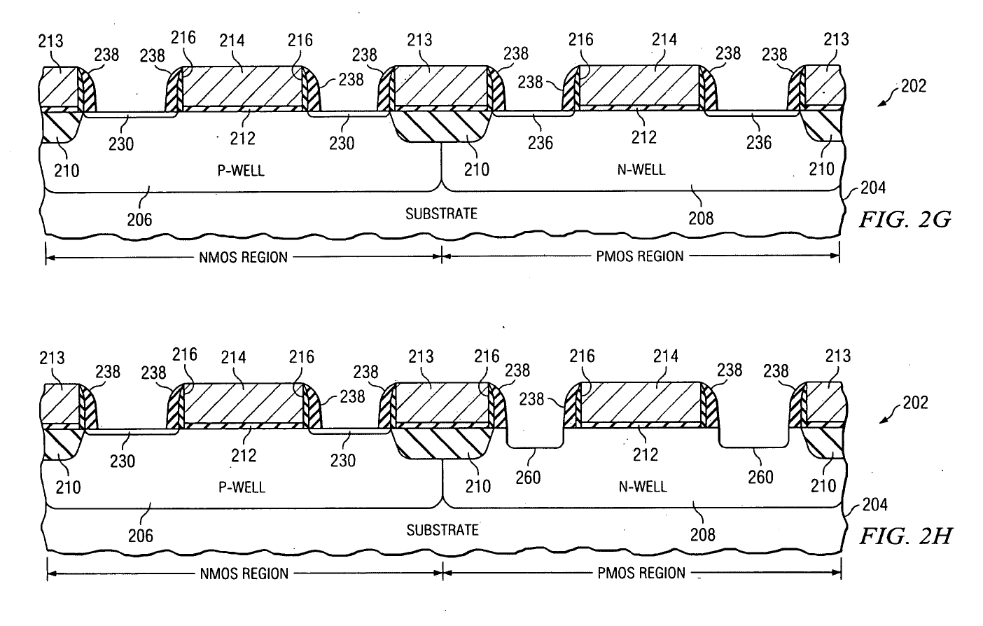

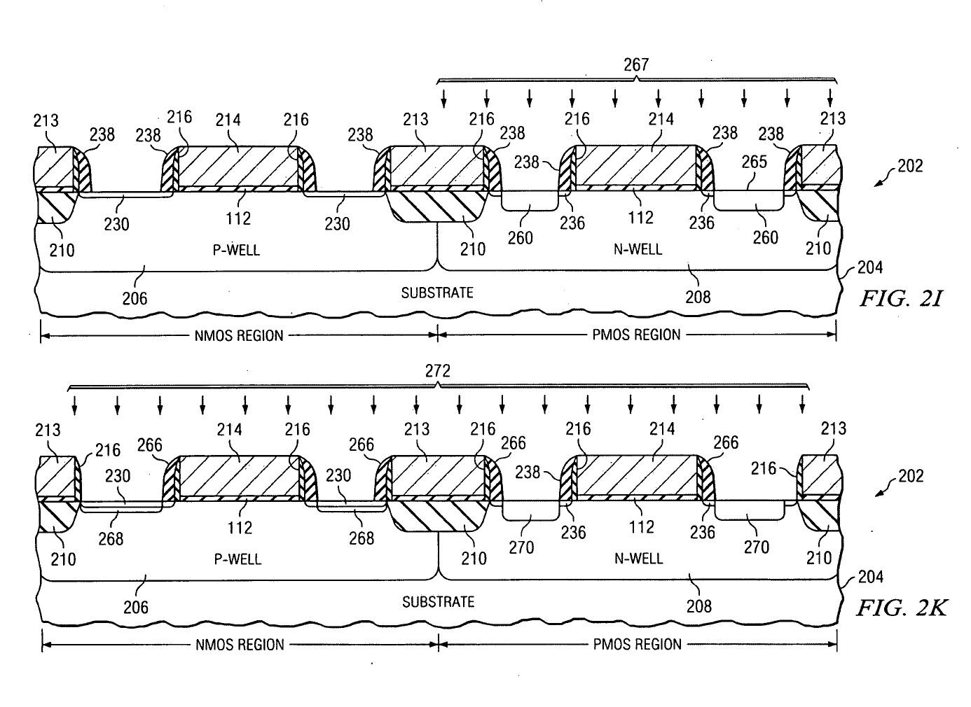

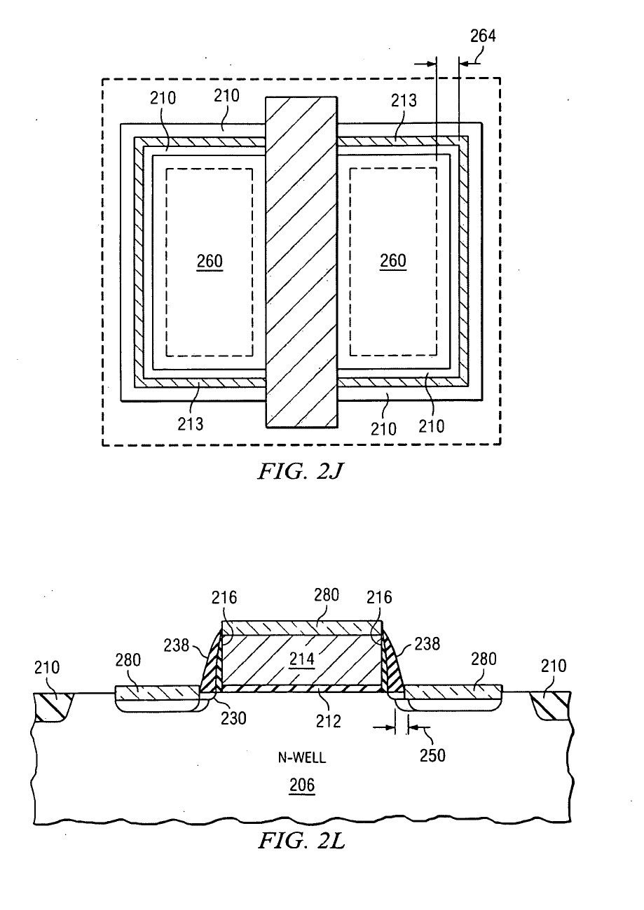

Methods for fabricating semiconductor devices having strain engineering while minimizing defects associated with strained silicon devices, for example, faceting, in accordance with various embodiments of the invention will now be described. Referring now to FIGS. 1 and 2A-2K, further aspects of the invention relating to methods of fabricating semiconductor devices in accordance with the invention are illustrated. In addition, the methods according to the invention embodiments can be implemented in association with the fabrication of IC's and composite transistors illustrated herein, as well as in association with other transistors and structures not illustrated, including but not limited to NMOS and/or PMOS composite transistors.

FIG. 1 illustrates an exemplary method 100 in accordance with the invention, and FIGS. 2A-2K illustrates the exemplary semiconductor device at various stages of fabrication in accordance with the invention. While the exemplary method 100 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the fabrication of ICs and composite transistors illustrated and described herein, as well as in association with other transistors and structures not illustrated, including but not limited to NMOS and/or PMOS composite transistors.

The method 100 begins at 102, wherein device fabrication is initiated and well formation and isolation processing is performed at 104. Act 104 thus defines NMOS and PMOS regions, wherein NMOS regions comprise a P-well in which n-type source/drain regions will later be formed, and PMOS regions comprise an N-well in which p-type source/drain regions will later be formed, respectively. In addition, isolation regions may comprise shallow trench isolation (STI) or field oxide regions (FOX) that serve to define various active areas and electrically isolate various active areas laterally from one another.

The method 100 continues at 106, wherein a gate oxide layer is formed in active areas defined by the various formed isolation regions. In one example, the gate oxide comprises a thin, thermally grown silicon dioxide layer; however, other type gate dielectrics (such as high-k dielectrics) may be formed and are contemplated by the present invention. A conductive gate layer is then deposited over the gate oxide at 108 and patterned to form a conductive gate electrode. For example, a polysilicon layer may be deposited via chemical vapor deposition (CVD) and patterned via etching to form gate electrodes in both NMOS and PMOS regions, respectively, as well as disposable or “dummy” gates over isolation regions.

An offset spacer is then formed on lateral edges of the conductive gate electrodes and dummy gate electrodes at 110. For example, a thin offset layer of an oxide is formed generally conformally over the patterned gate and then etched using a generally anisotropic dry etch to remove offset layer material on top of the gate and in the source/drain regions, leaving a thin offset spacer material on lateral edges of the gate. The offset spacer, as will be further appreciated below, is employed in this example to space away the strain inducing material slightly away from the channel region under the gate, for example, a distance of about 5 nm to about 30 nm.

Extension region implants can then be formed at 112 where p-type dopants are implanted in the PMOS region to form a p-type extension region, and n-type dopants are implanted in the NMOS region to form a n-type extension region.

Still referring to FIG. 1, sidewall spacers are then formed on the gate structures at 114, including disposable or “dummy” sidewall spacers on the dummy gate electrodes. The sidewall spacers comprise an insulating material of a nitride. The spacers are formed by depositing a layer of such spacer material(s) over the device in a generally conformal manner, followed by an anisotropic etch thereof, thereby removing such spacer material from the top of the gate structure and from the moat or active area and leaving a region on the lateral edges of the gate structure, overlying the offset spacers. The sidewall spacers are substantially thicker than the offset spacers, thereby resulting in the subsequently formed source/drain regions to be offset from lateral edges of the gate structure at least about 60 nm.

A recess is then formed in the moat area extending between the gate structure and the isolation regions at 116 in the PMOS region. The moat area refers to the active region of the silicon body where extension regions and subsequently source/drain regions may be formed. The recess is formed using, for example, a dry etching process such as the chemistry employed to etch STI trenches in the semiconductor body when forming isolation regions.

The method 100 then continues at 118, wherein silicon germanium is formed in the recesses. In one example, the silicon germanium is formed via a selective epitaxial deposition process such as an LPCVD (low pressure chemical vapor deposition) process using dichlorosilane and germane as the source gases. While not intending to be limited to any one theory, it is believed that the silicon germanium within the recesses form an alloy that has a lattice with the same structure as the silicon body lattice, however, the silicon germanium has a larger spacing. Consequently, it is believed that the silicon germanium within the recesses will tend to expand, thereby creating a compressive stress within the channel of the semiconductor body underneath the channel.

After filling recesses with semiconductor material (e.g., silicon germanium) source/drain sidewall spacers can be formed at 120. Source/drain sidewall spacers comprise an insulating material such as an oxide, a nitride, or a combination of such layers. Sidewall spacers can be formed as described hereinabove. The source/drain regions are then formed by implantation at 122, wherein a source/drain dopant is introduced into the exposed areas (top of gate electrode and active areas not covered by sidewall spacers). The source/drain regions are then completed with a thermal process to activate the dopant.

The method 100 then concludes with silicide processing at 124, wherein a metal layer is formed over the device, followed by a thermal process, wherein the metal and silicon interfaces react to form a silicide (on top of the gate and in the source/drain regions). Unreacted metal is then stripped away, and back end processing such as interlayer dielectric and metallization layers are formed at 128 to conclude the device formation at 128.

Turning now to FIGS. 2A-2K, a plurality of fragmentary cross section diagrams illustrating a transistor device being formed in accordance with the method of FIG. 1 is provided. In FIG. 2A, a transistor device 202 is provided, wherein a semiconductor body 204, such as a substrate, has a number of wells formed therein, such as a P-well 206 to define an NMOS transistor device region and an N-well 208 to define a PMOS transistor device region, respectively. Further, isolation regions 210 such as field oxide (FOX) or STI regions are formed in the semiconductor body to define active area regions 211.

In FIG. 2B, the transistor device 202 is illustrated, wherein a gate dielectric 212 has been formed, for example, thermally grown SiO₂, over the active areas 211. However, other types of gate dielectrics (such as high-k dielectrics) can be formed and are contemplated by the various embodiments.

Referring to FIGS. 2C and 2D, a conductive gate electrode material, such as, for example, polysilicon, can be deposited and patterned by an etching process 215 to form a gate electrode 214 overlying the gate oxide 212. Concurrently, dummy gates 213 are formed overlying gate oxide 212 in STI regions 210. Offset spacer 216 can then be formed on the lateral edges of the gate electrode 214 and dummy gate electrode 213, as seen in FIG. 2D, wherein the offset spacers can have a width 216A of about 10-50 nm.

The PMOS region can then be masked off, as illustrated in FIG. 2E with a masking material 226 such as photoresist, and an extension region implant 228 can be performed to form n-type extension region 230 in the NMOS region. According to various embodiments, a thermal process, such as a rapid thermal anneal, can then be performed to activate the dopant, wherein lateral diffusion of the extension regions 230 under the offset spacer 216 is achieved. Exemplary temperatures for activating dopants are from about 650° C. to about 1050° C. In certain embodiments, the temperature can be about 950° C. and in still further embodiments, the temperature can be about 1050° C. At these temperatures, there is amorphous layer re-growth.

The p-type extension region mask 226 can then be removed, and an n-type extension region mask 232 can be deposited and patterned to cover the NMOS region, as illustrated in FIG. 2F. A p-type extension region implant process 234 can then be performed to form p-type extension regions 236 in the PMOS region, as illustrated.

The mask 232 can then be removed and sidewall spacers 238 can then be formed adjacent offset spacers 216 on the lateral edges of the gate structures 214, including dummy sidewall spacers on dummy gate 213. For example, an insulating sidewall material of a nitride can be deposited in a generally conformal manner over the device and subsequently subjected to an anisotropic etch to remove the insulating material on top of the gate and over the active areas, leaving sidewall spacers 238 in both the NMOS and PMOS regions, as illustrated in FIG. 2G. Exemplary materials used for the dummy sidewall spacers 238 include various nitrides, such as silicon nitrides.

Recesses 260 can then be formed in the areas defined by sidewall spacers 238 and extending between the gate structure and the isolation regions in the PMOS region, as shown in FIG. 2H, with a mask in the NMOS region (not shown). The area where the recesses are formed can include the active regions of the silicon body where extension regions 230 and 236 and source and drain regions 268 and 270 (FIG. 2K) are formed. Recesses 260 can be formed using, for example, a dry etching technique such as the chemistry employed to etch the STI trenches in the semiconductor body when forming isolation regions. According to various embodiments, the recesses can extend into the semiconductor body to a depth of about 120 nm to about 130 nm.

As shown in FIG. 2I, recesses 260 can then be filled with a semiconductor material 265 by a selective epitaxial deposition process 267 whereby a germanium containing gas source such as germane is added to a silane or dichlorosilane, such that a silicon germanium material 265 is formed in the recesses 260. The amount of germanium in the silicon germanium material will be from about 20% wt to about 40% wt.

As shown in FIG. 2K, after filling the recesses with semiconductor material 265, sidewall spacers 266 can be formed thereafter. Source and drain regions 268 and 270 can then be formed in the NMOS and PMOS regions respectively, as shown in FIG. 2K. As discussed above in conjunction with the extension region implants, the source/drain implants 272 can be performed with a n-source/drain mask (not shown) and a p-source/drain mask (not shown) in order to implant the NMOS region and the PMOS region separately with n-type and p-type dopant, respectively.

According to various embodiments, as shown for example in FIG. 2L which is an enlarged view of a resulting PMOS transistor fabricated in accordance with the invention, a silicide 280 can then be formed. For example, a metal layer can be deposited, for example, by sputtering, followed by a thermal process. During the thermal process, those regions where the metal contacts silicon, reacts to form a metal silicide. More particularly, the silicide can then form on the source/drain regions and on top of the gates. Unreacted metal is then stripped away, and back end processing such as interlayer dielectric and metallization layers are formed so as to conclude the device formation.

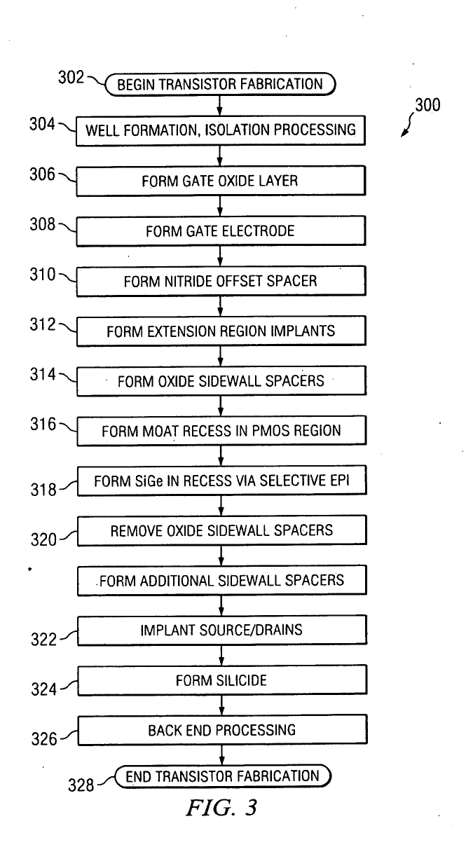

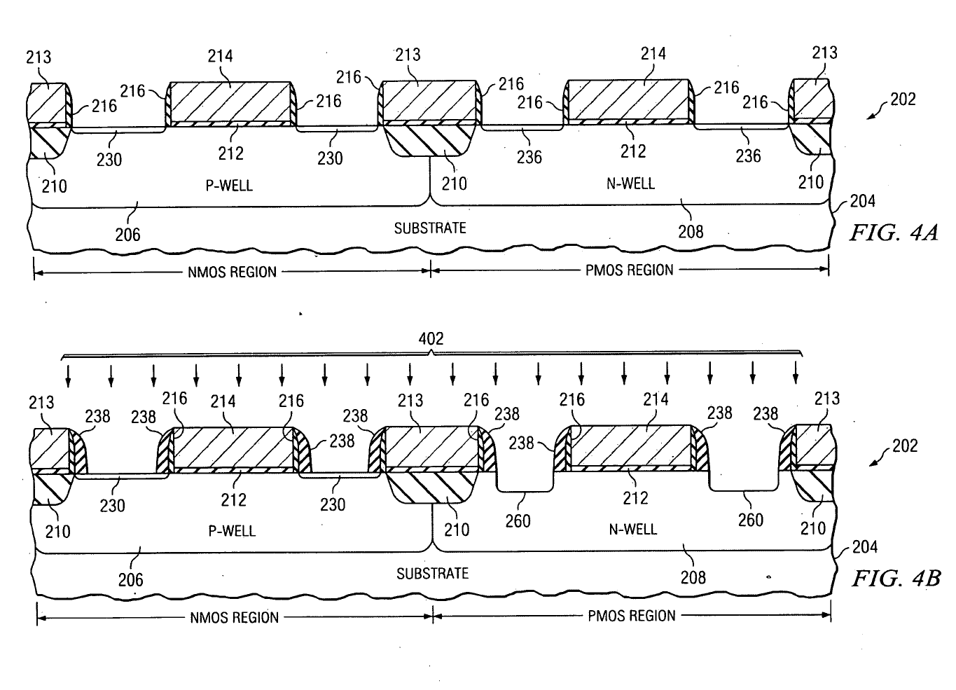

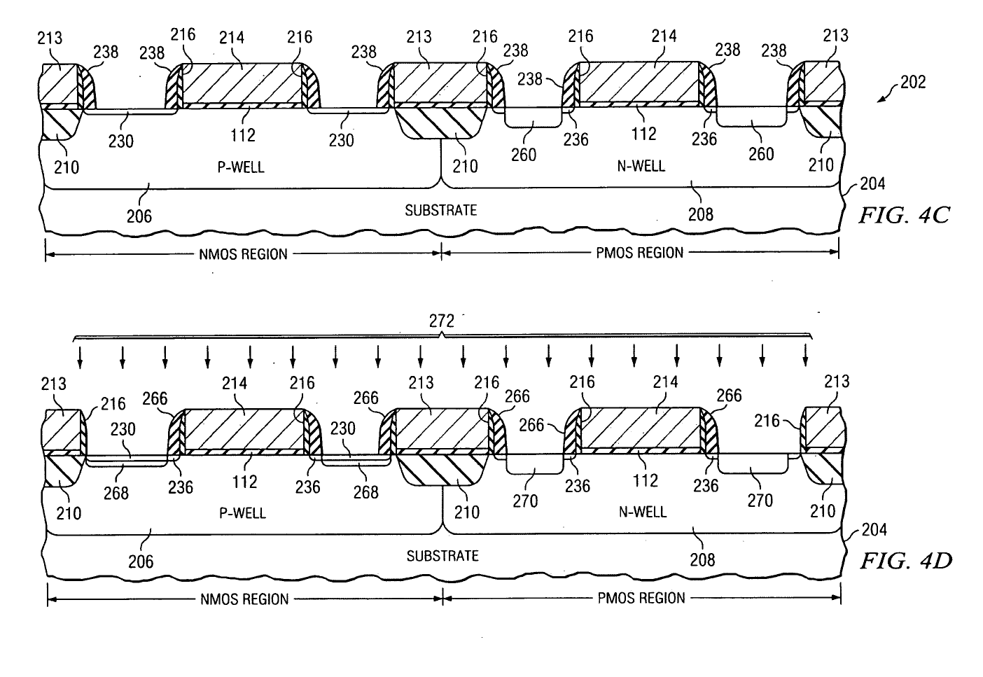

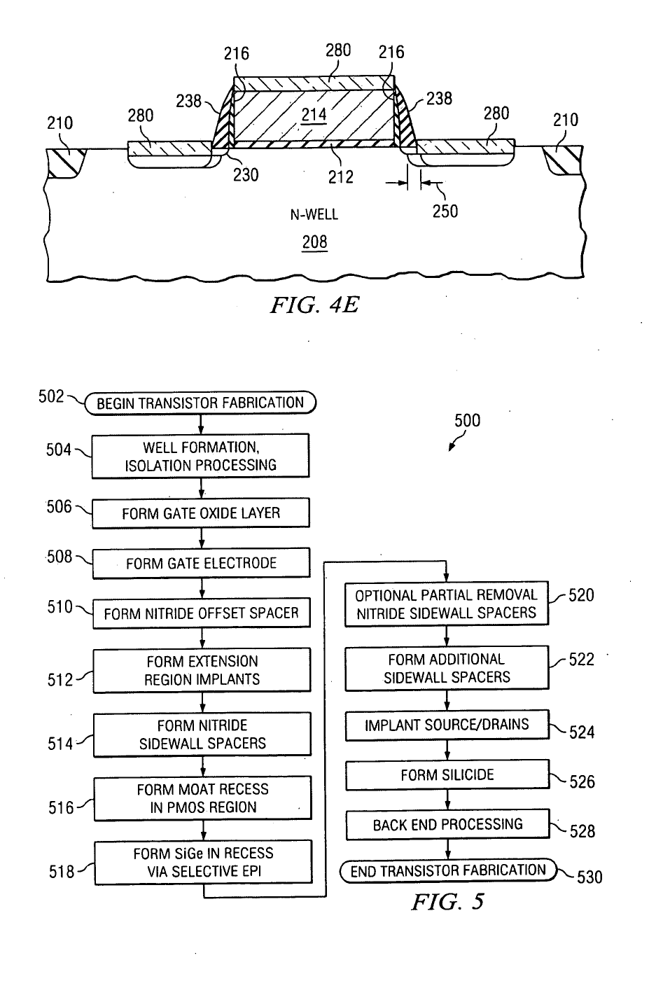

In an alternative embodiment of the invention, such as where an isotropic etch is utilized to form recesses, and referring to FIGS. 3 and 4A-4E, there is illustrated a method 300 in accordance with the invention, in which semiconductor processing proceeds as in method 200. The method 300 is similar in many respects to the method 200 of FIG. 1, and with regards to such aspects, those portions will not be repeated again. For example, acts 104-110 may proceed generally in the same manner as method 100. However, offset spacers are formed from a nitride insulating material, while sidewall spacers 338 are formed from an oxide insulating material. The method 300 may then proceed at 116-118 in a manner similar to that of method 200. Following epitaxial growth of silicon germanium material in the recesses, sidewall spacers are removed at 120. The method 300 then proceeds in the same manner as that of method 200.

FIGS. 4A-4F illustrates the fabrication of the transistor devices in accordance with the method 300 of FIG. 3. In FIG. 4A, a transistor device 202 has NMOS and PMOS regions as before with P-well and N-well regions 206 and 208 formed in a semiconductor body 204. Isolation regions 210 also are provided to define active areas for fabrication of transistor devices. A gate oxide 212 overlies the active regions and a patterned conductive gate electrode 214 and dummy gate 213 is formed thereover. Offset spacers 216 of a nitride material reside on lateral edges of the gate 214 and an extension region implant process 312 (e.g., an n-type followed by a p-type) is provided in conjunction with appropriate masking to form extension regions 230 and 236, respectively. A subsequent thermal anneal causes the extension regions 230 and 236 to diffuse laterally to extend slightly under the offset spacers 216.

Oxide sidewall spacers 238 are then formed and recesses 260 are then formed in the active areas (and on top of the gate electrodes 214) in the PMOS region after the extension region implant via an etch process 402, as illustrated in FIG. 4B with a mask (not shown) in the NMOS region.

Silicon-germanium material 265 is formed in the recesses 260 and on top of the gate electrode as illustrated in FIG. 4C, via a selective epitaxial deposition process 318. Oxide sidewall spacers 238 are then removed.

FIGS. 4D-4E progress similarly to that described in the previous method, wherein sidewall spacers are formed, followed by the source/drain implants 268 and 270 (in NMOS regions and then PMOS regions, respectively) and then silicidation 280.

Turning now to FIG. 5, a method 500 is disclosed in accordance with the invention, wherein acts 504-518 proceed in a similar manner to method 200 discussed supra. However, the oxide spacers 216 are formed from a nitride insulating material, and the sidewall spacers 238 are also formed from a nitride insulating material. At 520 sidewall spacers 238, in one embodiment, will not be removed. In an alternative embodiment, sidewall spacers may be partially removed. The method 500 may then proceed at 522-528 in a manner similar to that of method 200.

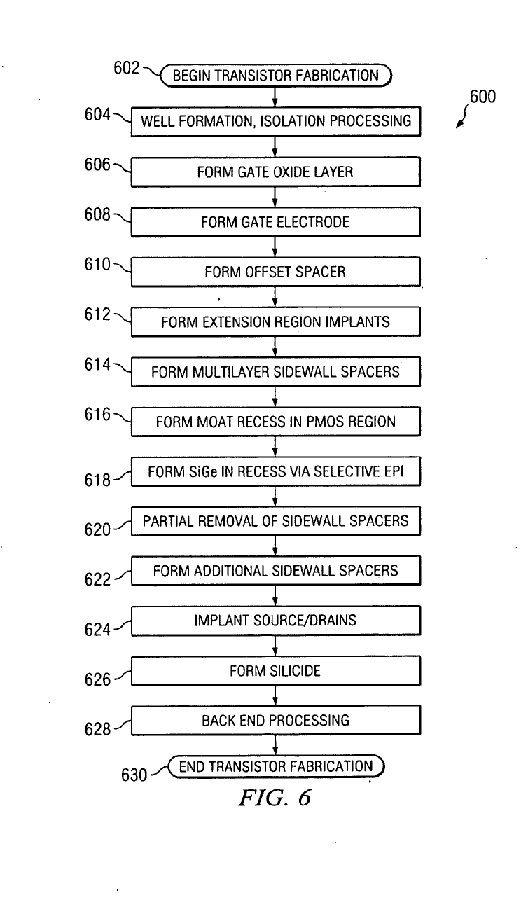

In method 600, as illustrated in FIG. 6, in accordance with the invention, acts 602 through 612 proceed in a similar manner to method 200 discussed supra. At 614, a multilayer sidewall spacer is formed (e.g. oxide+nitride). The method 600 then continues with formation of silicon germanium in recesses 616, followed by partial removal of the sidewall spacer. For example, where the sidewall spacer is formed in layers of nitride and oxide, the oxide portion is removed. The method 600 may then proceed at 622 through 628 in a manner similar to the method of 200.

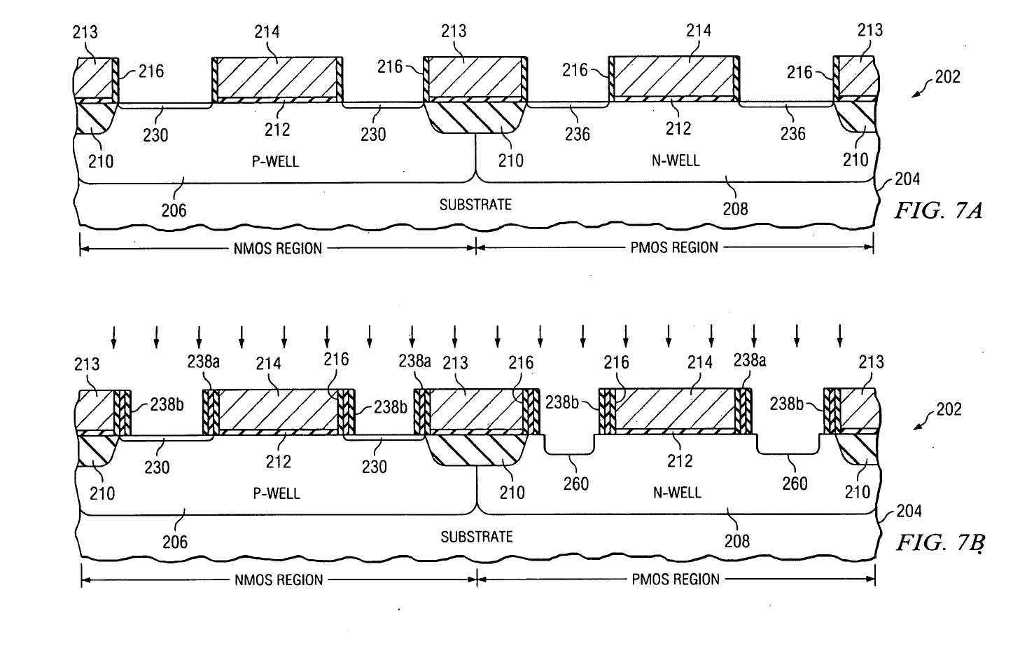

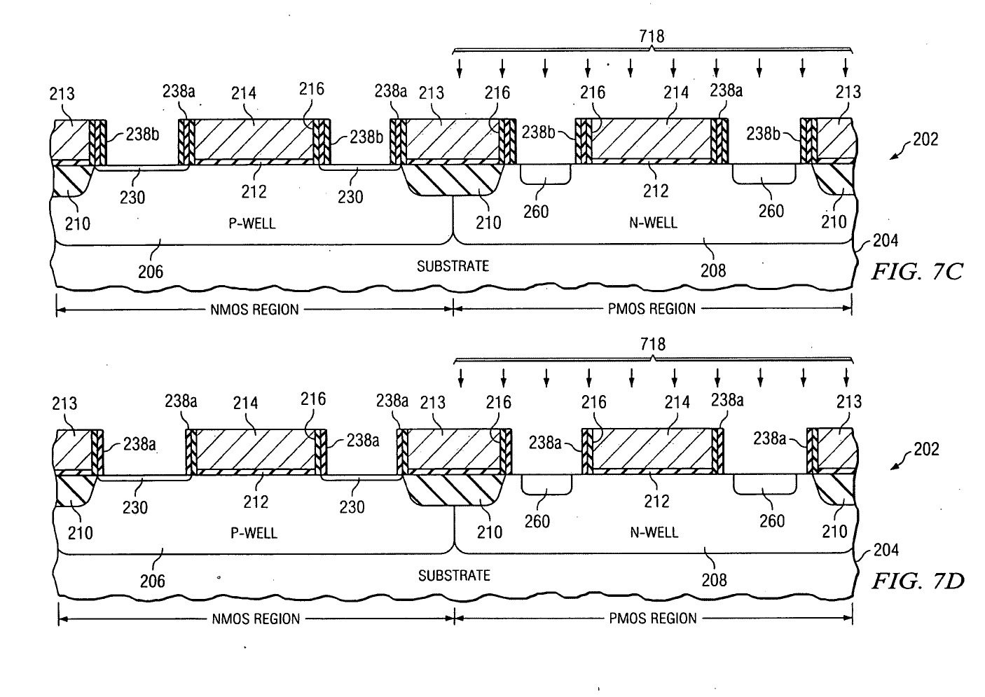

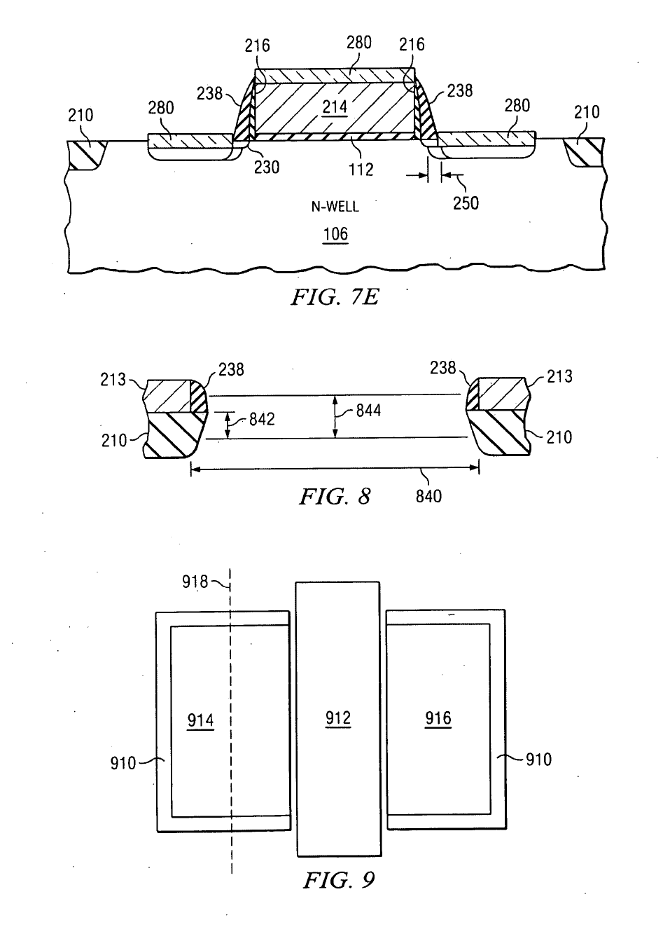

FIGS. 7A-7F illustrates the fabrication of the transistor devices in accordance with the method 600 of FIG. 6. In FIG. 6A, a transistor device 202 has NMOS and PMOS regions as before with P-well and N-well regions 206 and 208 formed in a semiconductor body 204. Isolation regions 210 also are provided to define active areas for fabrication of transistor devices. A gate oxide 212 overlies the active regions and a patterned conductive gate electrode 214 and dummy gate 213 is formed thereover. Offset spacers 216 of a nitride material reside on lateral edges of the gate 214 and an extension region implant process 312 (e.g., an n-type followed by a p-type) is provided in conjunction with appropriate masking to form extension regions 230 and 236, respectively. A subsequent thermal anneal causes the extension regions 230 and 236 to diffuse laterally to extend slightly under the offset spacers 216.

Multilayer sidewall spacers of a nitride 238a+oxide 238b are then formed and recesses 260 are then formed in the active areas in the PMOS region (and on top of the gate electrodes 214) after the extension region implant via an etch process 402, as illustrated in FIG. 4B, with a mask in the NMOS region (not shown).

Silicon-germanium material 265 is formed in the recesses 260 and on top of the gate electrode as illustrated in FIG. 7C, via a selective epitaxial deposition process 718.

The oxide portion 238b of sidewall spacers 238 are then removed in FIG. 7D and the method progresses similarly to that described in the previous method, wherein the source/drain implants 268 and 270 (in NMOS regions and then PMOS regions, respectively) and then silicidation 280.

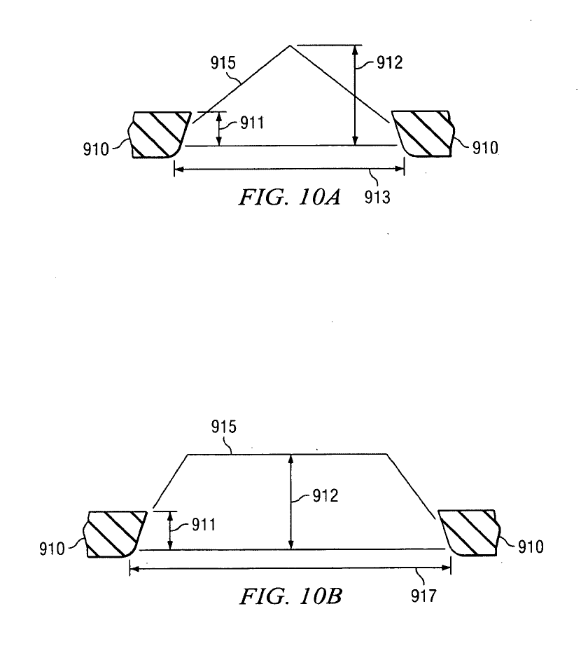

Turning to FIG. 9, there is illustrated a top plan view of a source 914/drain 916 having a gate electrode 912 and isolation regions 910, in which FIGS. 10A and 10B illustrate narrow width 913 and large width 917 devices along cutline 918 (FIG. 9), respectively. In conventional methods of forming silicon-germanium layers, epitaxial silicon-germanium growth 912 from recesses, having depth 911, between isolation regions 910 resulted in faceting 915 of the silicon germanium. As illustrated in FIG. 2J, which is a top plan view on the middle of a source/drain, and FIG. 8, which is a cross section along the width 840 of the source/drain region, addition of the dummy gate 213 and dummy sidewall spacers 238 of the invention results in spacing 264 of the recesses 260, having a depth 842, from the STI structures 210, thus allowing for growth of the silicon germanium material 265 vertically 844 along the dummy sidewalls 238 and preventing faceting of the silicon germanium along the STI interface. Alternatively, where the STI is an oxide structure, the silicon germanium material 265 will grow from deep within the structure such that near the surface of the STI, the material will be at a lower height. In such a case, the sidewall spacers 238 provide support for the growing silicon germanium front as it grows above the silicon surface, and spacing of the recesses from the STI structures 210 is not necessary.

In addition, while the invention is described above with respect to the use of germanium to form a silicon germanium lattice structure, the present invention contemplates the use of any element that will create an alloy with silicon and serve to impart a compressive stress to the channel of the PMOS devices, and such alternatives are contemplated as falling within the scope of the invention.

While the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of forming a semiconductor device comprising:
forming gates over a substrate, the gates including disposable gates overlying isolation regions;
forming oxide offset spacers and nitride sidewall structures on sidewalls of the gates;
forming recesses in areas defined by sidewall structures;
filling with an epitaxially grown semiconductor material;
forming a source region and a drain region by doping a first portion and a second portion of an active regions adjacent a gate; and
activating the dopants in the source region and the drain region by heating the active regions.

2. The method of claim 1, wherein the substrate is a silicon substrate.

3. The method of claim 1, wherein recesses extend into substrate to a depth of about 120 nm to about 130 nm.

4. The method of claim 3, wherein the sidewall spacers have a width of about 10 nm to about 60 nm.

5. The method of claim 3, wherein the disposable sidewall spacer comprises a silicon nitride.

6. The method of claim 1, wherein the semiconductor material comprises silicon germanium.

7. The method of claim 3, wherein the amount of germanium present in the semiconductor material is from about 20 at wt % to about 50 at wt %.

8. The method of claim 1, wherein the semiconductor material deposited forms a strained region with respect to the surrounding source region and drain region, respectively.

9. A method of forming a semiconductor device comprising:
forming gates over a substrate, the gates including disposable gates overlying isolation regions;
forming nitride offset spacers and oxide sidewall structures on sidewalls of the gates;
forming recesses in areas defined by sidewall structures;
filling with an epitaxially grown semiconductor material;
removing oxide sidewall structures;
forming a source region and a drain region by doping a first portion and a second portion of an active regions adjacent a gate; and
activating the dopants in the source region and the drain region by heating the active regions.

10. The method of claim 9, forming recesses in areas defined by sidewall structures comprises an isotropic etch.

11. The method of claim 9, wherein the semiconductor material comprises silicon germanium.

12. The method of claim 11, wherein the amount of germanium present in the semiconductor material is from about 20 at wt % to about 50 at wt %.

13. The method of claim 9, wherein the semiconductor material deposited forms a strained region with respect to the surrounding source region and drain region, respectively.

14. A method of forming a semiconductor device comprising:
forming gates over a substrate, the gates including disposable gates overlying isolation regions;
forming nitride offset spacers and nitride sidewall structures on sidewalls of the gates;
forming recesses in areas defined by sidewall structures;
filling with an epitaxially grown semiconductor material;
forming a source region and a drain region by doping a first portion and a second portion of an active regions adjacent a gate; and
activating the dopants in the source region and the drain region by heating the active regions.

15. The method of claim 14 further comprising partially removing the nitride sidewall spacer.

16. A method of forming a semiconductor device comprising:
forming gates over a substrate, the gates including disposable gates overlying isolation regions;
forming offset spacers and multilayer sidewall structures on sidewalls of the gates;
forming recesses in areas defined by sidewall structures;
filling with an epitaxially grown semiconductor material;
removing a portion of the multilayer sidewall structure;
forming a source region and a drain region by doping a first portion and a second portion of an active regions adjacent a gate; and
activating the dopants in the source region and the drain region by heating the active regions.

17. The method of claim 16, wherein the multilayer sidewall structure comprises and oxide portion and a nitride portion.

18. The method of claim 17, wherein removing a portion of the sidewall structure comprises removing the nitride portion of the multilayer sidewall structure.

19. The method of claim 16, wherein the semiconductor material comprises silicon germanium.

20. The method of claim 16, wherein the semiconductor material deposited forms a strained region with respect to the surrounding source region and drain region, respectively.
